(19) United States
(12) Patent Application Publication
(10) Pub. No.: US 2016/0126382 A1
(43) Pub. Date: May 5, 2016

(54) ENERGY CONVERSION DEVICE WITH MULTIPLE VOLTAGE OUTPUTS AND POWER TRANSISTOR MODULE USING THE SAME

(71) Applicant: MH GOPOWER CO., LTD., KAOHSIUNG CITY (TW)

(72) Inventors: MEI-HUAN YANG, KAOHSIUNG CITY (TW); TERRY ZAHURANEC, KAOHSIUNG CITY (TW); REMIGIO PERALES, KAOHSIUNG CITY (TW); CHENG-LIANG WU, KAOHSIUNG CITY (TW); WEI-SHENG CHAO, KAOHSIUNG CITY (TW); CHIN-WEI HSU, KAOHSIUNG CITY (TW); TE-CHIH HUANG, KAOHSIUNG CITY (TW); JHENG-SYUAN SHIH, KAOHSIUNG CITY (TW); PEI-YA WANG, KAOHSIUNG CITY (TW)

(21) Appl. No.: 14/753,515

(22) Filed: Jun. 29, 2015

Related U.S. Application Data
(63) Continuation-in-part of application No. 14/530,619, filed on Oct. 31, 2014.

(51) Int. Cl. H01L 31/047; H03K 17/687; H01L 25/16; H01L 31/024; H01L 23/367

(52) U.S. Cl. CPC H01L 31/047; H01L 31/024; H01L 23/3675; H01L 25/167; H03K 17/687

(57) ABSTRACT

An energy conversion device in electrical communication with at least one fin is provided to output multiple voltages. The at least one fin which is originating from inside the energy conversion device, which is formed from a metal contact disposed between energy conversion device components, and which is spaced with a first end contact and a second end contact. A power transistor module includes at least one transistor, a gate driver and the energy conversion device. The gate driver is configured to drive the at least one transistor. The energy conversion device is configured to supply isolated voltages to the gate driver.

### CROSS-REFERENCES TO RELATED APPLICATIONS

This patent application claims priority from and is a continuation-in-part of U.S. patent application Ser. No. 14/530,619 filed Oct. 31, 2014, which in turn claims priority from U.S. patent application Ser. No. 14/324,040 filed Jul. 3, 2014. The entirety of each of these patent applications is incorporated herein by reference in its entirety.

### FIELD

The disclosure relates to an energy conversion device, more particular to an energy conversion device with multiple voltage outputs and a power transistor module using the same.

### BACKGROUND

Multiple voltage sources have found a wide range of applications in different areas including charging devices or power transistor modules such as insulated gate bipolar transistor (IGBT) module or metal-oxide-semiconductor field effect transistor (MOSFET) module. Conventional multiple voltage sources utilize separate battery banks or batteries connected in series to provide multiple voltages. However, batteries are heavy and only store a small amount of electricity, which cannot be used for high-voltage charging devices or power transistor modules.

High-voltage IGBT's are commonly used as modules with ratings from 15 to 3,000 V and higher, aimed at inverters, converters, power supplies, motor control and traction applications. At least one gate driver is needed to drive the IGBT's. Particularly, the gate driver for power inverters and converters requires electrical isolation. Batteries cannot provide isolated voltages to match the gate driver needs. Therefore, an isolation transformer connected to the gate driver is provided to isolate the output voltages. Thus the IGBT's can rapidly switch between their operational on and off states in response to the gate driver.

In general, the isolation transformer has solid magnetic cores to provide galvanic isolation between circuits. However, it causes an increase in cost because high voltage isolation transformers are typically custom-built. Moreover, high voltage isolation transformers are heavy and huge in order to obtain the high isolation voltages. For example, typical dimensions of an isolation transformer with an isolation voltage of 20 kV, are 200 mm×200 mm×200 mm at a weight of approximately 5.5 kg.

The vertical multi-junction (VMJ) cell is a high-voltage energy conversion device which has a small feature size and light weight, and allows output voltages higher than single junction cells. Typically a 10 mm×10 mm VMJ cell can generate a voltage of no less than 25 volts under one sun illumination whereas conventional single junction cells can only generate a few volts at best. Nevertheless, the conventional VMJ cell only has a voltage output from two end contacts. Therefore, generating multiple voltage outputs is still challenging to modern VMJ cells.

In view of the foregoing, it is greatly desired to develop an energy conversion device which may output multiple voltages and replace the isolation transformer in power transistor modules.

### SUMMARY OF THE INVENTION

In accordance with one aspect of the present disclosure, an energy conversion device in electrical communication with at least one fin is provided to output multiple voltages. The at least one fin which is originating from inside the energy conversion device, which is formed from a metal contact disposed between energy conversion device components, and which is spaced with a first end contact and a second end contact.

In accordance with another aspect of the present disclosure, a power transistor module includes at least one transistor, a gate driver and an energy conversion device. The gate driver is configured to drive the at least one transistor. The energy conversion device is configured to supply isolated voltages to the gate driver.

In the present disclosure, the energy conversion device can output multiple voltages by contacting the at least one fin and different end contacts, or other fins. Furthermore, the energy conversion device can provide a noise free voltage source, and the output voltages of the energy conversion device can be regarded as non-transformer isolated voltages. Therefore, the energy conversion device is suitable for replacing an isolation transformer in power transistor module.

### BRIEF DESCRIPTION OF THE DRAWINGS

FIG. 1 shows an oblique surface schematic view of a prior art edge-illuminated vertical multijunction photovoltaic receiver array, illustratively shown with schematic thermal flow;

FIG. 2 shows an oblique surface schematic view of a individual cell from a prior art vertical multijunction photovoltaic receiver array;

FIG. 3 shows a cross-sectional schematic diagram of a prior art edge-illuminated vertical multijunction photovoltaic receiver array, showing mounting and schematic thermal flow;

FIG. 4 shows a cross-sectional schematic diagram of a general energy conversion device similar to the illustrative vertical multijunction photovoltaic receiver of FIG. 3, with schematic illustrative thermal flow;

FIG. 5 shows a close-up view of the cross-sectional schematic diagram of the general energy conversion device of FIG. 4, showing thermal flow and energy carriers essential to function of the device, with a heat sink formed separately and in thermal communication across an interface;

FIG. 6 shows a top partial surface view, looking down, of a relatively flat general energy conversion device like that shown in FIGS. 4 and 5, but embodying the instant invention and employing cooling fins formed from energy conversion device components;

FIG. 7 shows a simplified schematic thermal flow chart for a prior art general energy conversion device using a conventional prior art heat sink;

FIG. 8 shows a simplified schematic thermal flow chart for a general energy conversion device cooled using the instant invention;

FIGS. 9-11 show oblique surface views of three illustrative prior art three-dimensional energy conversion or optoelectronic device billets that can be improved by practicing the invention, with incident beams impinging upon or emerging from billet entry sides;

FIG. 12 shows an oblique surface view of an energy conversion device illustratively shown as a relatively flat vertical multijunction photovoltaic cell array with heat sinking provided according to the instant invention;

FIG. 13 shows a close-up of a portion of the oblique surface view of the energy conversion device of FIG. 12, showing a thermal path for heat dissipation;

FIGS. 14 and 15 show oblique surface views of another embodiment of an energy conversion device illustratively shown as a relatively flat vertical multijunction photovoltaic cell array with heat sinking provided according to the instant invention, featuring a thermal bed, and with the device of FIG. 15 comprising a retroreflector;

FIG. 16 shows an underside oblique surface view of the energy conversion device of FIG. 15, with the retroreflector tucked under the energy conversion device;

FIG. 17 shows an oblique surface view of an energy conversion device similar to that illustratively shown as a relatively flat vertical multijunction photovoltaic cell array with heat sinking provided according to the instant invention of FIG. 12, with energy conversion device components forming a heat sink array under the device;

FIG. 18 shows simplified schematic chart for a method for thermal communication according to the invention;

FIG. 19 shows an oblique surface view of an energy conversion device according to the invention with a heat sink array and heat sink holding structures;

FIG. 20 shows an oblique partial cut-out surface view of an energy conversion device illustratively shown as a three-dimensional optoelectronic device billet according to the invention similar to that shown in FIG. 19, and showing illustrative internal and external cooling systems inside the heat sink holding structure;

FIG. 21 shows a simple representative cartesian plot of the cell operating temperature of a energy conversion device vertical multijunction cell array as a function of incident intensity of light for photovoltaic conversion, for both a prior art device and a device using the instant invention;

FIGS. 22 and 23 show differing oblique surface views of a relatively flat energy conversion device with heat sinking according to the invention, using twin thermal beds;

FIG. 24 illustrates a perspective view of an energy conversion device in accordance with some embodiments of the present disclosure;

FIG. 25 illustrates a perspective view of an energy conversion device in accordance with some embodiments of the present disclosure;

FIG. 26 illustrates a schematic view of an energy conversion device in accordance with some embodiments of the present disclosure;

FIG. 27 illustrates a schematic view of an energy conversion device in accordance with some embodiments of the present disclosure;

FIG. 28 illustrates a perspective view of a power transistor module in accordance with some embodiments of the present disclosure;

FIG. 29 illustrates a top view of an energy conversion device in accordance with some embodiments of the present disclosure; and

FIG. 30 illustrates a cross-sectional view of a waveguide aligned to an energy conversion device in accordance with some embodiments of the present disclosure.

### DETAILED DESCRIPTION OF THE INVENTION

As described in parent U.S. patent application Ser. No. 14/530,619 (incorporated herein by reference), an energy conversion device in thermal communication with a plurality of fins at least partially forming a heat sink is provided. However, the energy conversion device in electrical communication with at least one fin can be used to output multiple voltages.

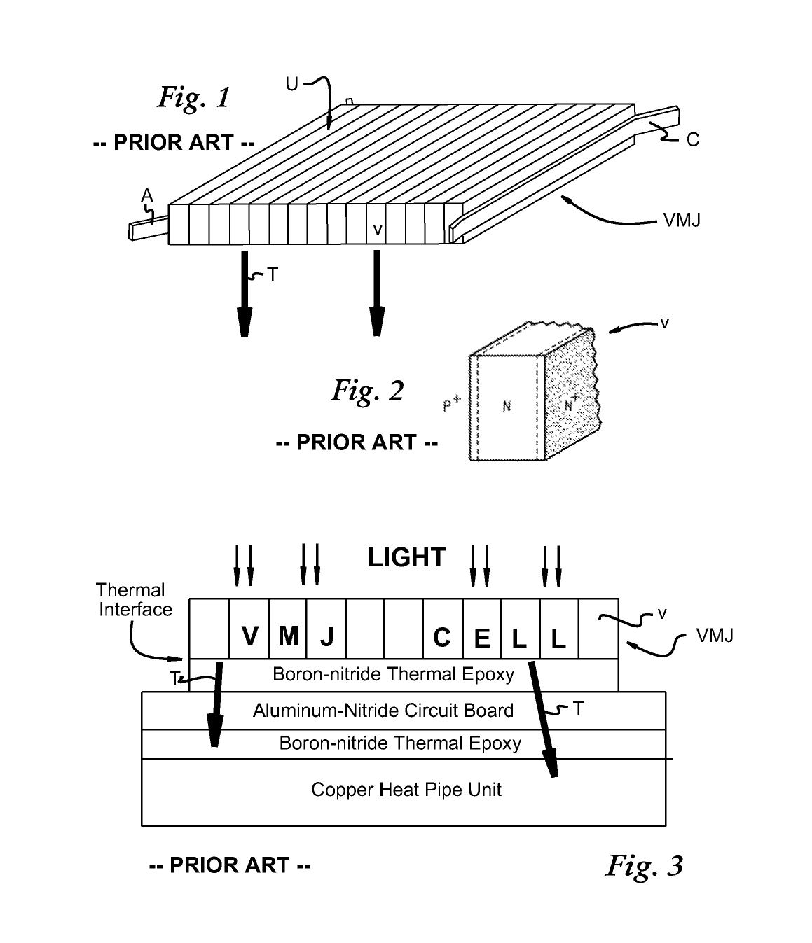

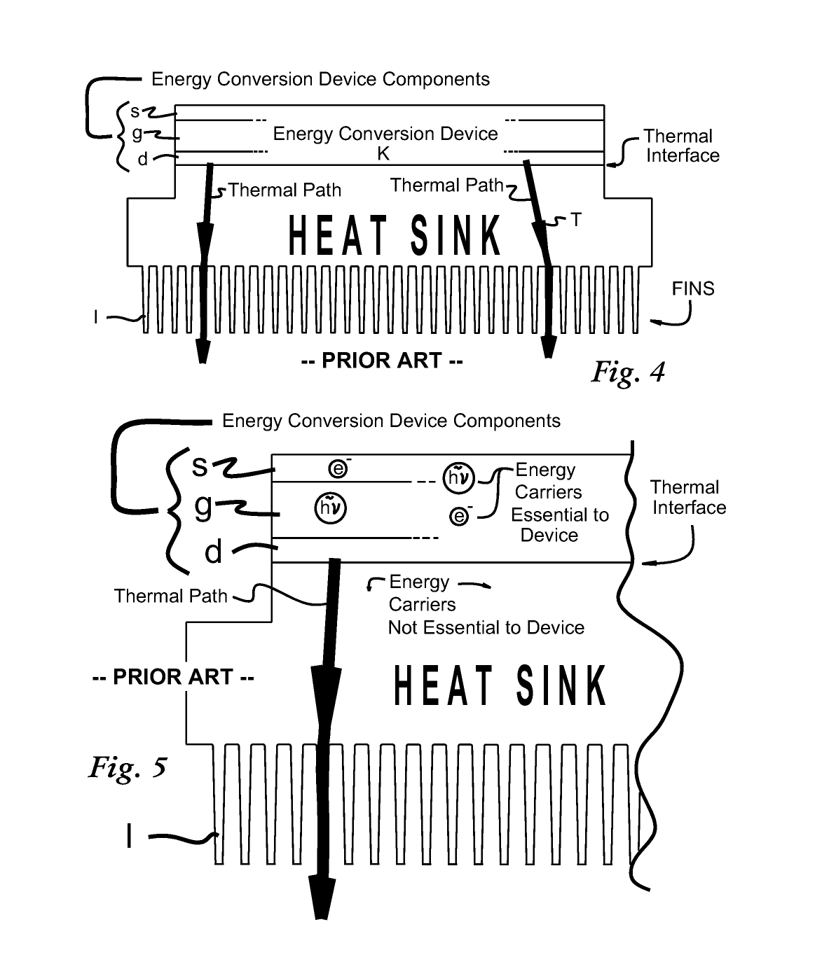

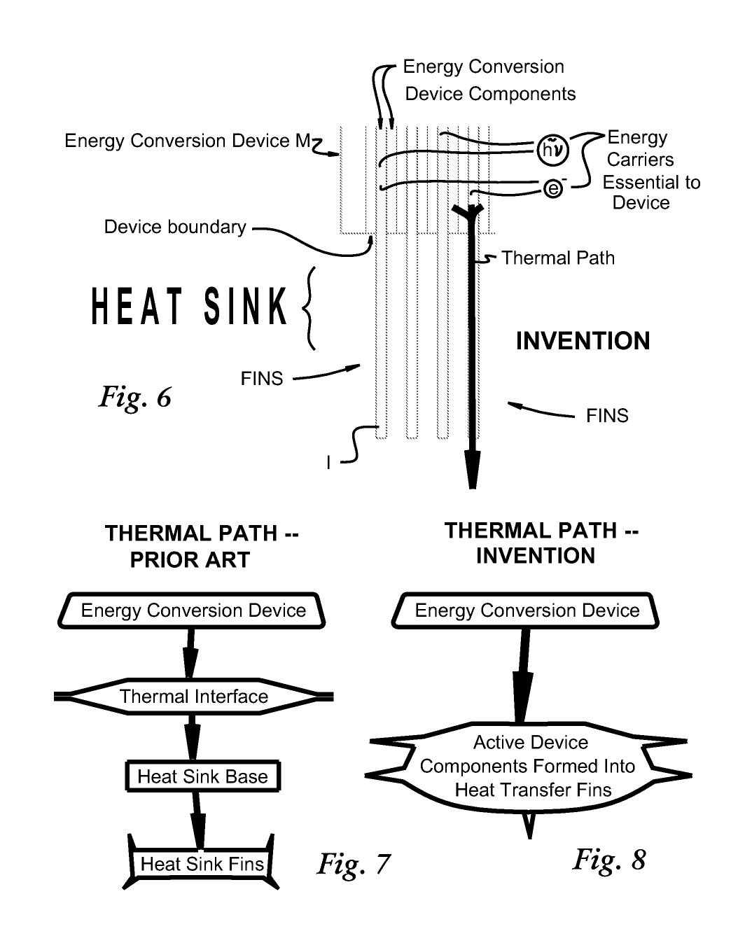

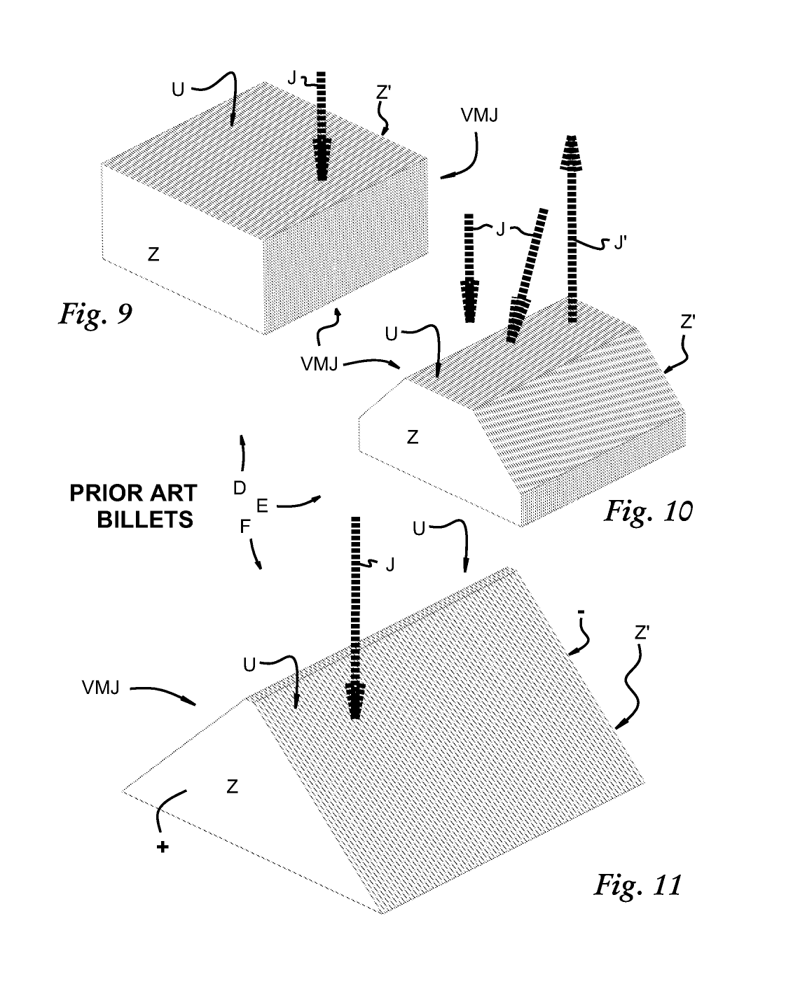

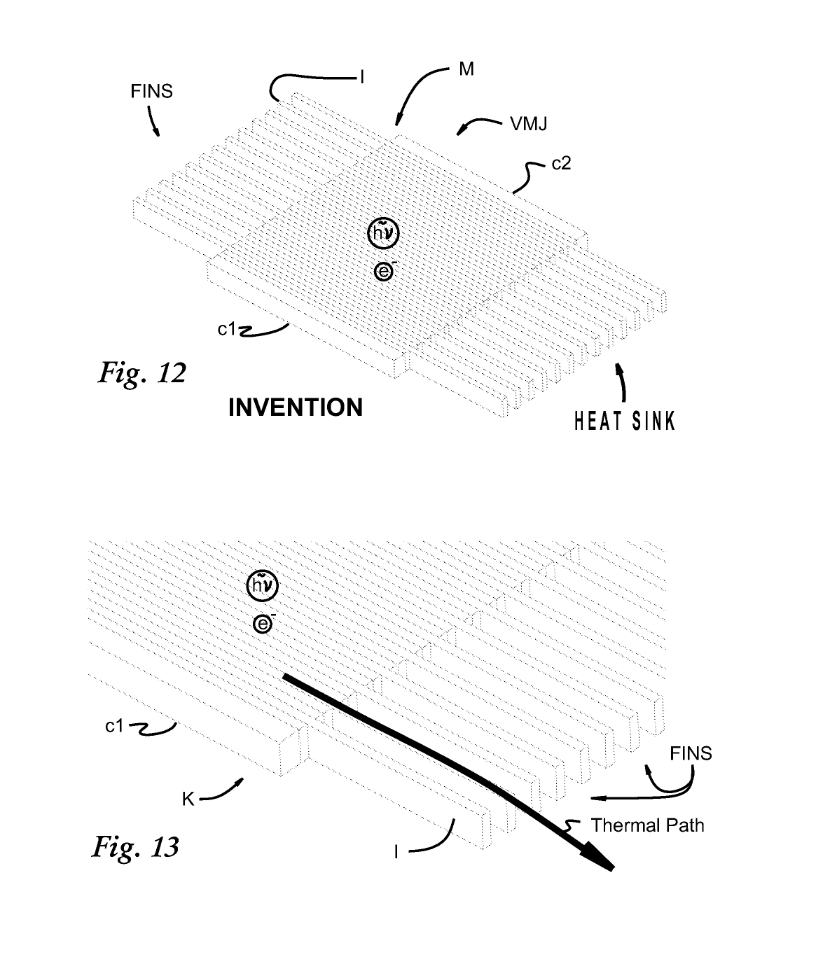

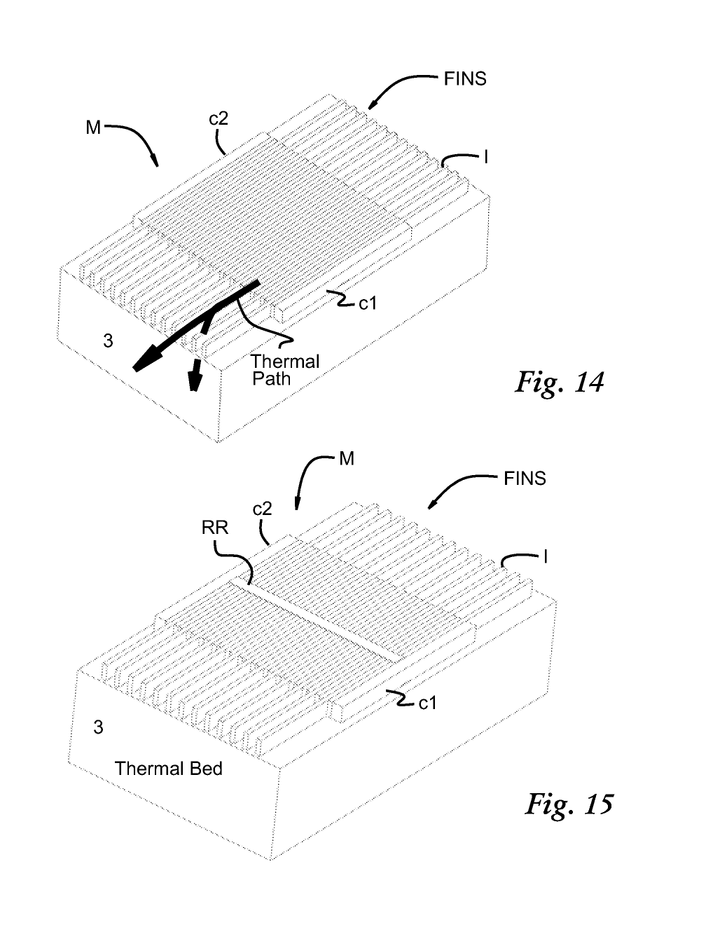

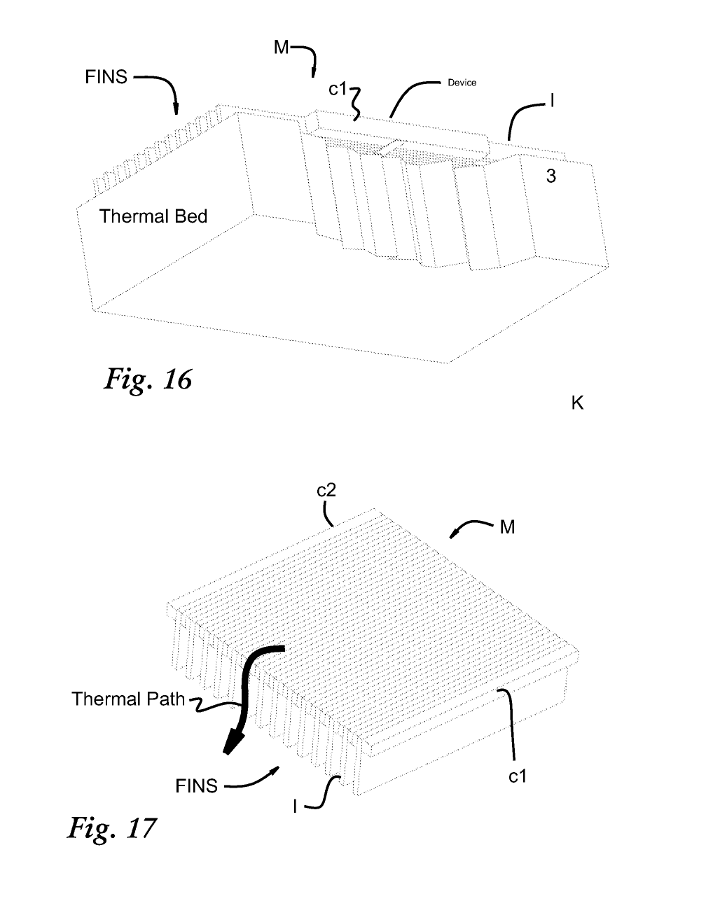

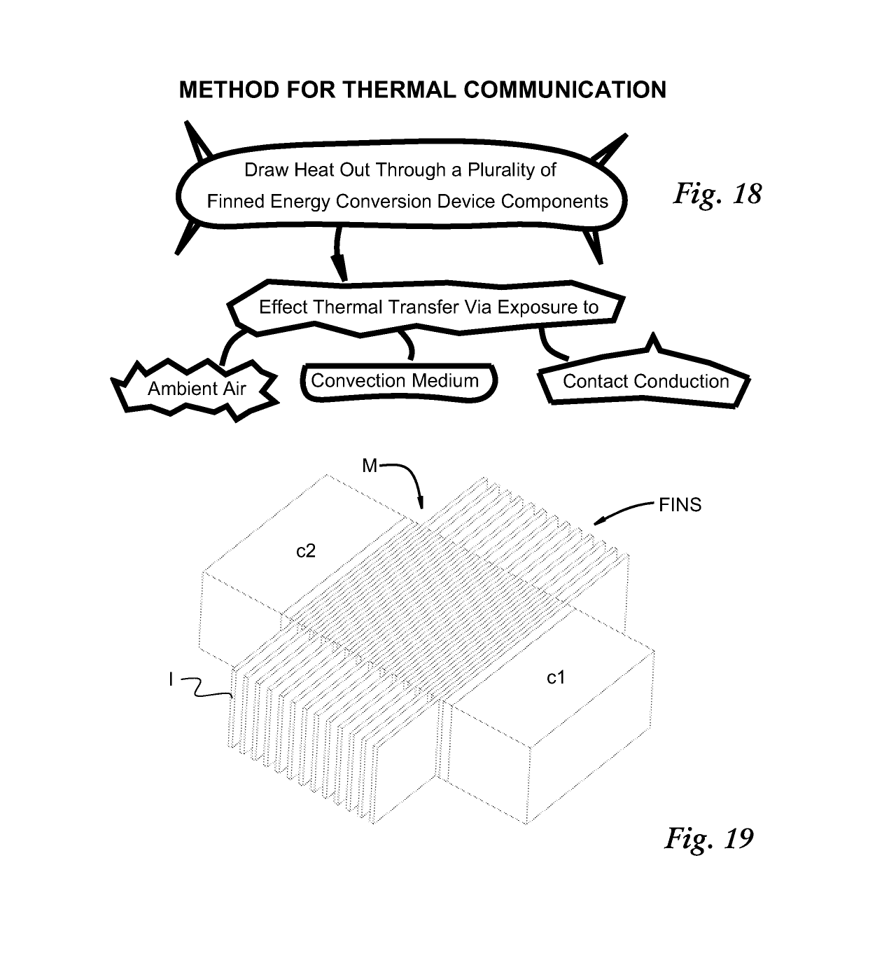

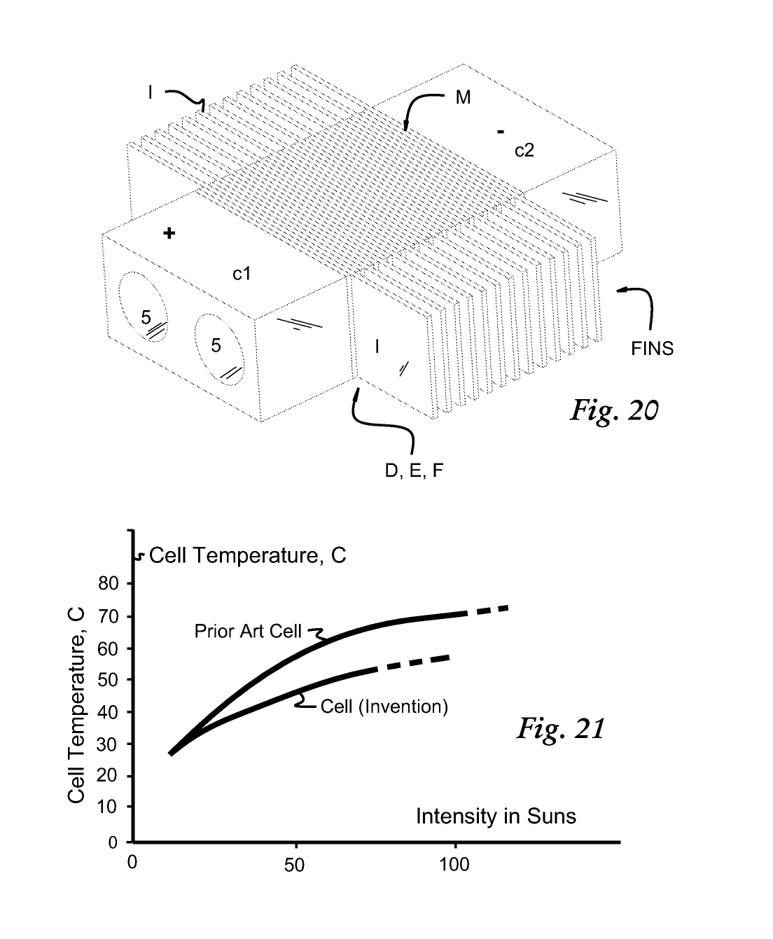

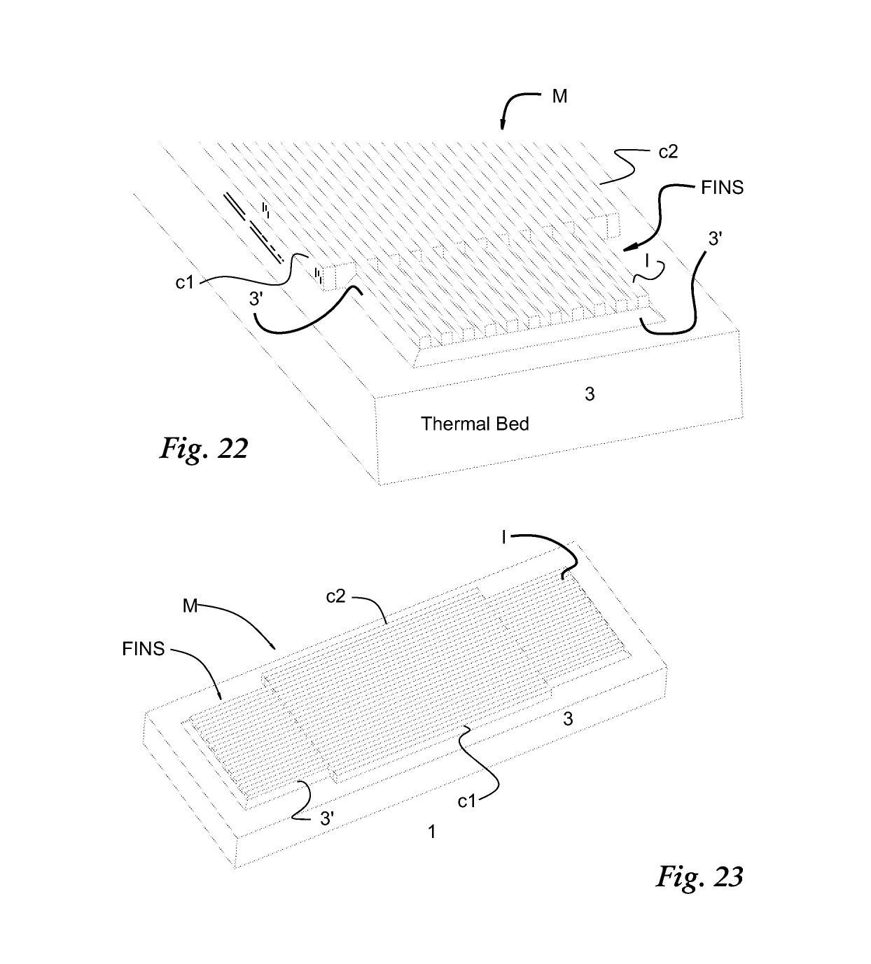

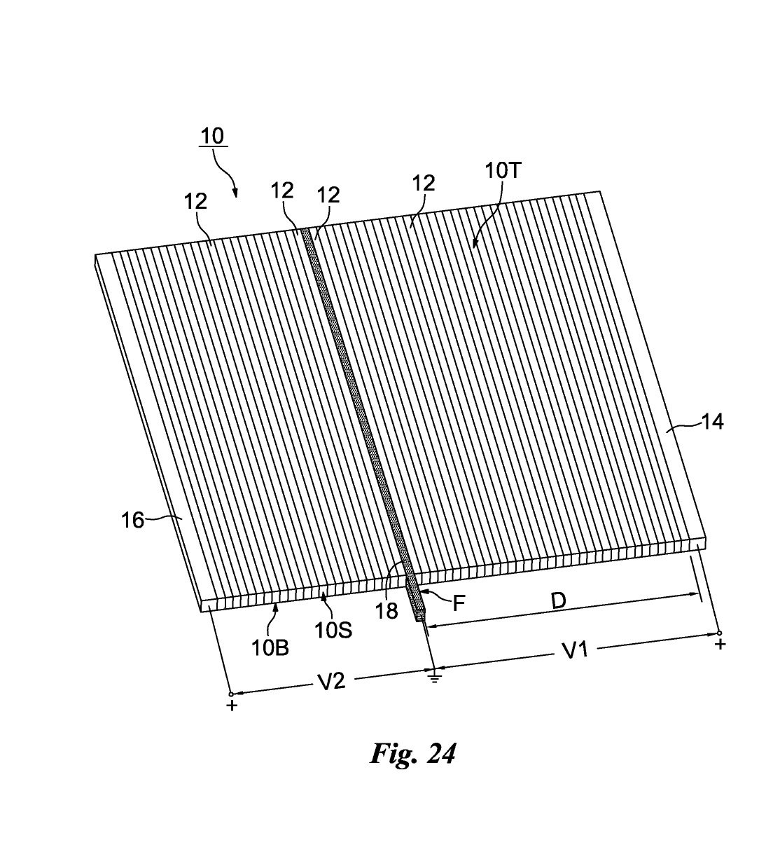

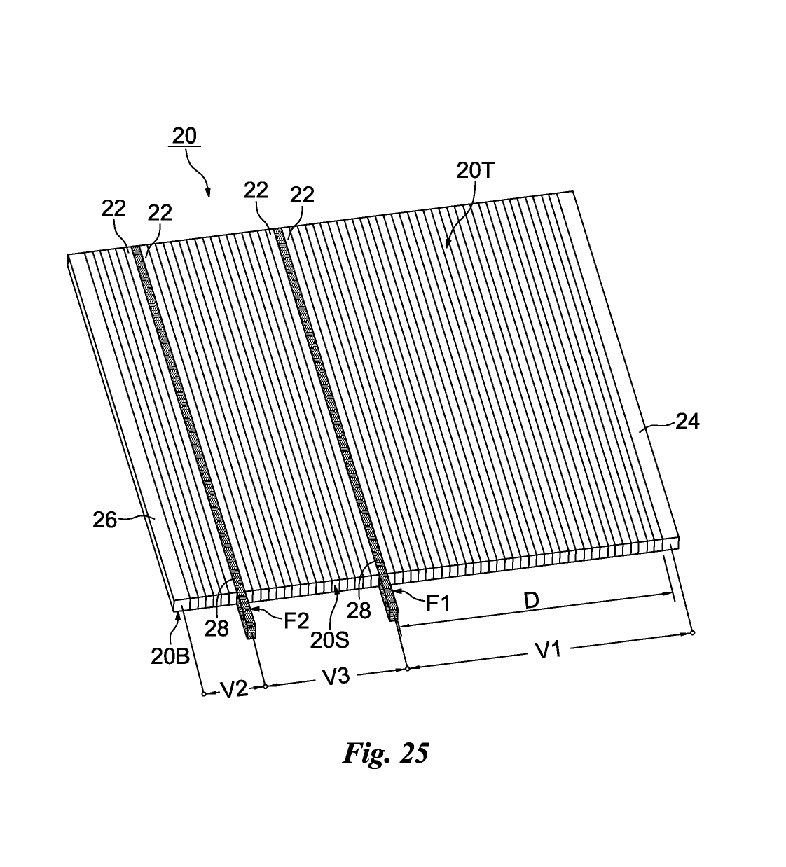

The “Definitions” and “Detailed Description” of FIGS. 1 to 23 of above-referenced U.S. patent application Ser. No. 14/530,619 are incorporated herein by reference as if expressly set forth.

Referring to FIG. 24, an energy conversion device 10 is designed to output multiple voltages. The energy conversion device 10 is in electrical communication with at least one fin F. In some embodiments, the energy conversion device 10 is also in thermal communication with the at least one fin F.

The energy conversion device 10 includes a plurality of energy conversion device components 12, a first end contact 14, a second end contact 16 and a metal contact 18. In this embodiment, the energy conversion device 10 is a vertical multijunction (VMJ) cell, and the energy conversion device components 12 are cell junctions of the vertical multijunction (VMJ) cell. The energy conversion device components 12 are stacked such that all the energy conversion device components 12 have their positive charged side facing the same direction, or stacked such that the energy conversion device components 12 have their positive charged side reversed on the other side of the metal contact 18. In some embodiments, the energy conversion device components 12 are reversed on the other side of the metal contact 18, wherein the number of junctions between end contacts 14, 16 and metal contacts 18, and between metal contacts 18, are the same, allowing for paralleling of each cell section. Furthermore, a high power laser can be used as the light source of the VMJ cell.

The energy conversion device components 12 are between the first end contact 14 and the second end contact 16. The metal contact 18 is disposed between the energy conversion device components 12. In some embodiments, the metal contact 18 is made of aluminum, kovar, copper, or any other electrically conducive metal.

The at least one fin F is originating from inside the energy conversion device 10. In this embodiment, the at least one fin F is formed from the metal contact 18 and is spaced with the first end contact 14 and the second end contact 16. In addition, the energy conversion device 10 has an end surface 10S, a top surface 10T and a bottom surface 10B, and the at least one fin F is protruding from the end surface 10S. In some embodiments the at least one fin F can protrude from the top surface 10T or the bottom surface 10B. In some embodiments, the at least one fin F, does not extend on either side of the energy conversion device 10 (VMJ cell) and is flush with the energy conversion device components 12.

In some embodiments, the at least one fin F is a common ground fin, enabled by reversing of the energy conversion device components 12 on the other side of the fin F. Therefore, the first end contact 14 and the common ground fin F can output a first voltage V1, and the second end contact 16 and the common ground fin F can output a second voltage V2. To make the energy conversion device 10 with a common ground, the process must be to have junctions for one end contact to the fin F (common ground) stacked in the reverse direction as junctions from the other end contact to the fin F (common ground). Furthermore, a distance D is between the first end contact 14 and the common ground fin F. The distance D is defined as a fraction of the full length of the energy conversion device 10. Preferably, the first voltage V1 is directly proportional to the distance D, and the second voltage V2 is inversely proportional to the distance D.

Based on the use of one fin F, the energy conversion device 10 can generate two voltage outputs, i.e. output two voltages (V1, V2). Certainly, more voltage outputs can be realized by increasing the number of fins F.

Referring to FIG. 25, an energy conversion device 20 is designed to output multiple voltages. The energy conversion device 20 is in electrical communication with a first fin F1 and a second fin F2. In some embodiments, the energy conversion device 20 is also in thermal communication with the first fin F1 and the second fin F2.

The energy conversion device 20 includes a plurality of energy conversion device components 22, a first end contact 24, a second end contact 26 and two metal contacts 28. In this embodiment, the energy conversion device 20 is a vertical multijunction (VMJ) cell, and the energy conversion device components 22 are cell junctions of the vertical multijunction (VMJ) cell.

The energy conversion device components 22 are between the first end contact 24 and the second end contact 26. Each of the metal contacts 28 is disposed between the energy conversion device components 22. In some embodiments, the metal contacts 28 are made of aluminum, kovar, copper, or any other electrically conducive metal.

The first fin F1 and the second fin F2 are originating from inside the energy conversion device 20 and are spaced from each other. In this embodiment, the first fin F1 and the second fin F2 are formed from different metal contacts 28 and are spaced with the first end contact 24 and the second end contact 26. In addition, the energy conversion device 20 has an end surface 20S, a top surface 20T and a bottom surface 20B, and the first fin F1 and the second fin F2 are protruding from the end surface 20S. In some embodiments, the first fin F and the second fin F2 can protrude from the top surface 20T or the bottom surface 20B. Furthermore, a distance D is between the first end contact 24 and the first fin F1.

As the configuration of the energy conversion device 20, many contact locations can be selected for outputting different voltages. In this embodiment, the first end contact 24 and the first fin F1 can output a first voltage V1. The second end contact 26 and the second fin F2 can output a second voltage V2. The first fin F1 and the second fin F2 can output a third voltage V3.

Preferably, the first voltage V1 is directly proportional to the distance D, and the sum of the second voltage V2 and the third voltage V3 is inversely proportional to the distance D.

Based on the use of the first fin F1 and the second fin F2, the energy conversion device 20 can generate three voltage outputs, i.e. output three voltages (V1, V2, V3). However, if the junctions are all in the same direction, then each voltage would have a different reference starting voltage. With this configuration, the voltages could be utilized by different circuits, or be isolated from each other for use by the same circuit. Although the energy conversion device 20 shown in FIG. 25 uses two fins, numerous configurations are within the contemplated scope of the present disclosure.

In the present disclosure, the energy conversion device can provide a noise free voltage source, and the output voltages and power of the energy conversion device can be regarded as non-transformer isolated voltages and power. Therefore, the energy conversion device is suitable for replacing an isolation transformer in power transistor module.

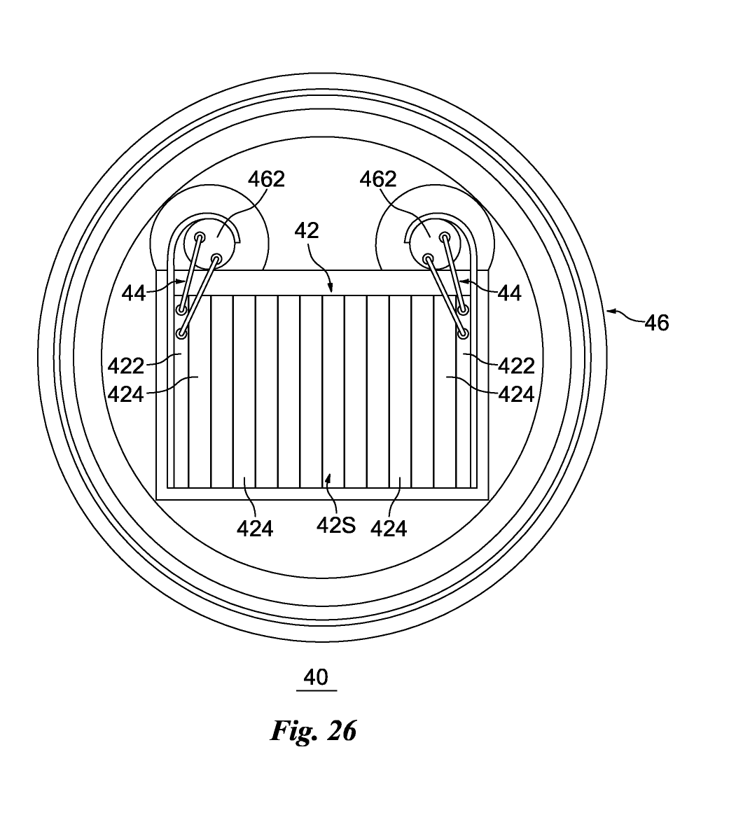

Referring to FIG. 26, an energy conversion device 40 is provided. The energy conversion device 40 includes a vertical multijunction (VMJ) cell 42 and a plurality of lead wires 44.

The vertical multijunction (VMJ) cell 42 includes a top surface 42S, two end contacts 422 and a plurality of cell junctions 424 disposed between the two end contacts 422. The lead wires 44 are respectively bonded to the end contacts 422. Furthermore, the lead wires 44 are bonded on the top surface 42S.

In this embodiment, the VMJ cell 42 can be disposed on a submount 46 for a hermetic TO-CAN package. The submount 46 has a plurality of electrically conductive pads 462, and the lead wires 44 are respectively connected to the electrically conductive pads 462 for outputting at least one voltage.

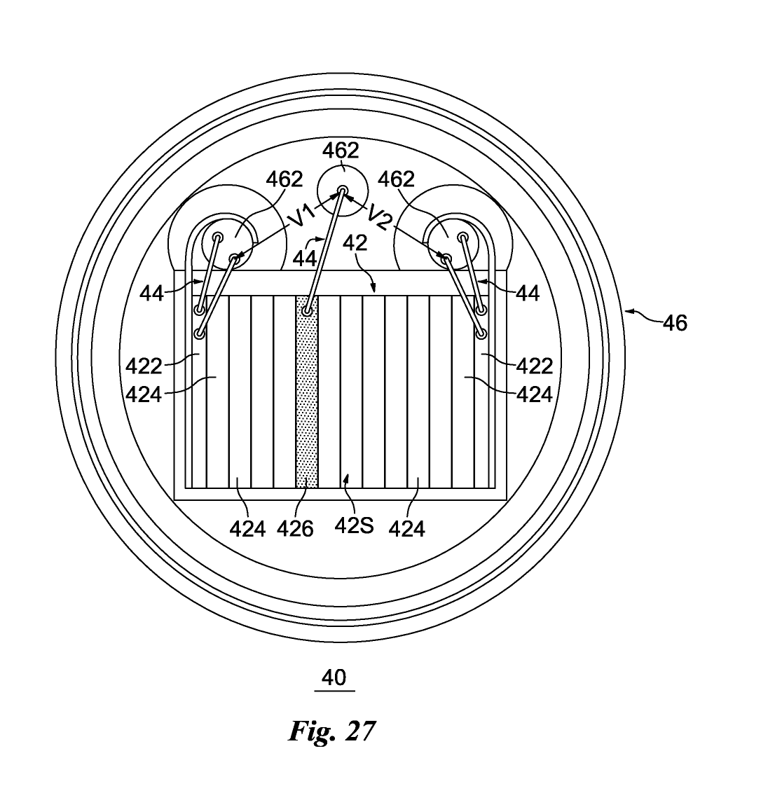

Referring to FIG. 27, in order to output multiple voltages, the VMJ cell 42 can include at least one metal contact 426 disposed between the cell junctions 424, and one of the lead wires 44 is bonded to the metal contact 426. When the metal contact 426 is defined as common ground, two voltages (V1, V2) can be outputted through the lead wires 44.

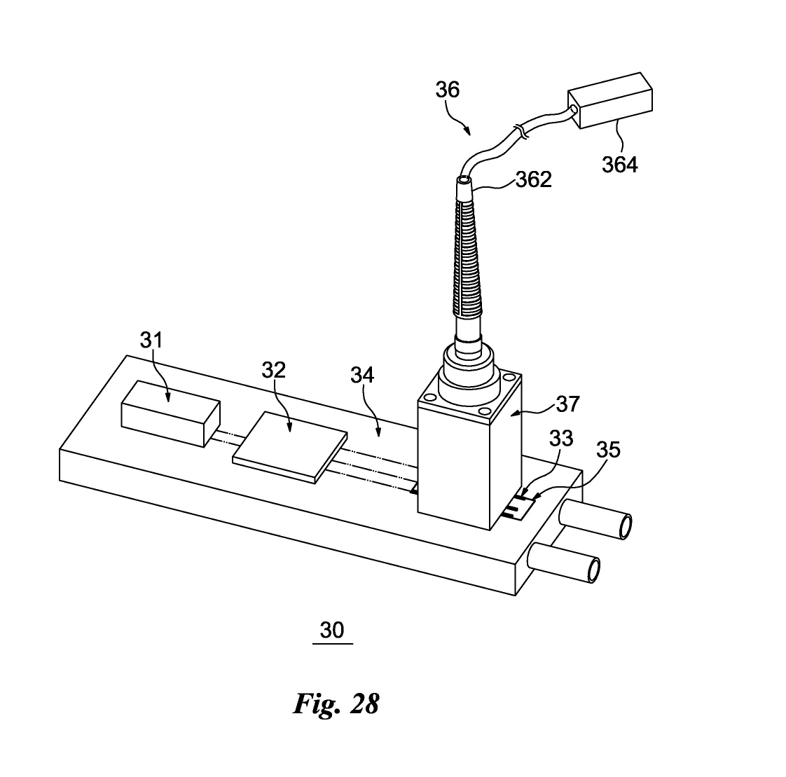

Referring to FIG. 28, a power transistor module 30 is provided. The power transistor module 30 includes at least one transistor 31, a gate driver 32 and an energy conversion device 33.

In some embodiments, the at least one transistor 31 can be an insulated gate bipolar transistor (IGBT) or a metal-oxide-semiconductor field effect transistor (MOSFET). The gate driver 32 is configured to drive the at least one transistor 31. For reliable transistor switching, the gate driver 32 requires a steady and robust isolated voltage.

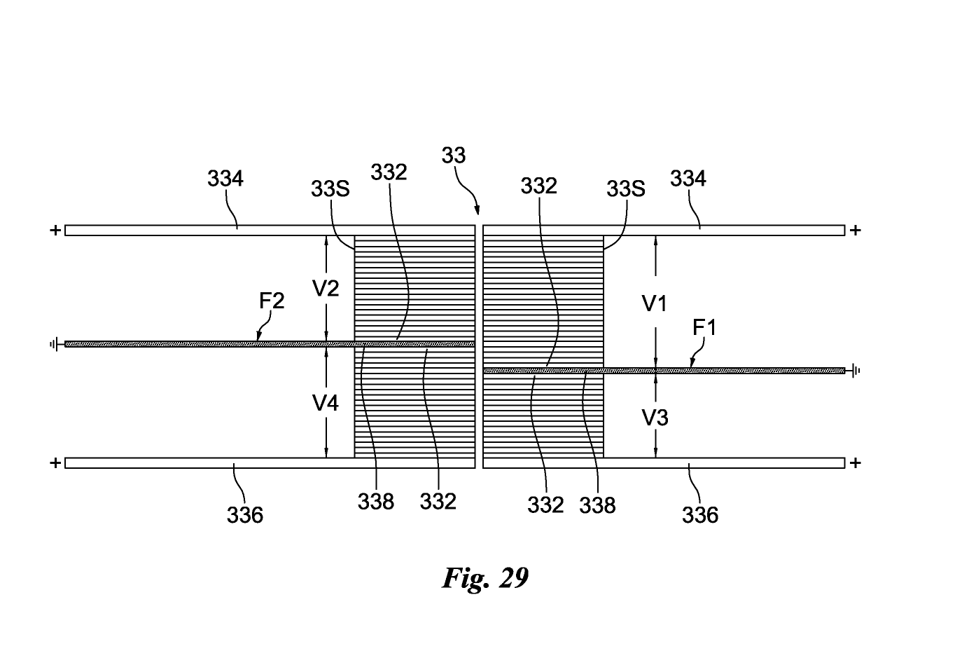

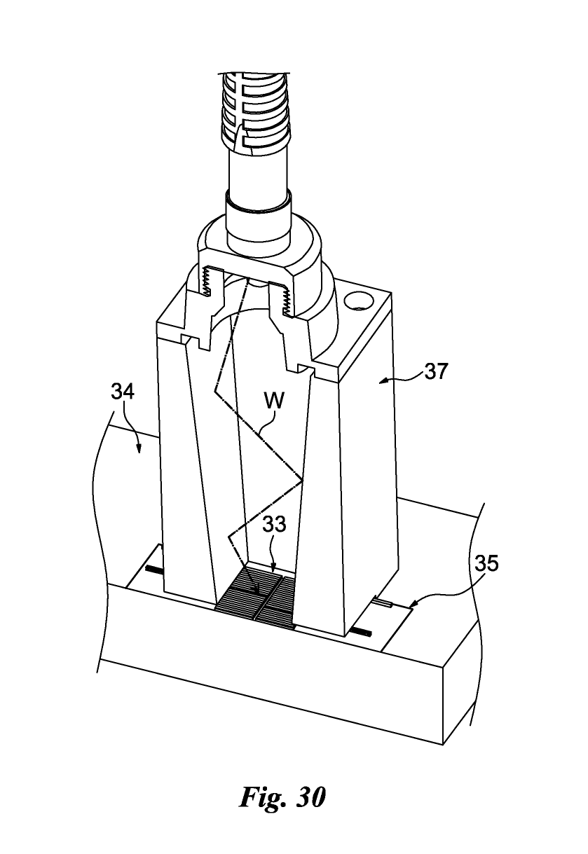

Referring to FIGS. 28 and 29, the energy conversion device 33 is configured to supply isolated voltages and power to the gate driver 32. In this embodiment, the at least one transistor 31 and the energy conversion device 33 can be disposed on a heat sink 34, such as a cold plate, to achieve heat dissipation. To improve heat dissipation rate, a thermal interface material 35 can be disposed between the energy conversion device 33 and the heat sink 34.

In this embodiment, the energy conversion device 33 is in electrical communication with a first fin F1 and a second fin F2. Certainly, in some embodiments, the energy conversion device 33 can be in electrical communication with one fin as the embodiment of FIG. 24.

The energy conversion device 33 includes a plurality of energy conversion device components 332, a first end contact 334, a second end contact 336 and two metal contacts 338. In this embodiment, the energy conversion device 33 is a vertical multijunction (VMJ) cell, and the energy conversion device components 332 are cell junctions of the vertical multijunction (VMJ) cell.

The energy conversion device components 332 are between the first end contact 334 and the second end contact 336. Each of the metal contacts 338 is disposed between the energy conversion device components 332. In some embodiments, the metal contacts 338 are made of aluminum, kovar, copper, or any other electrically conducive metal.

Referring to FIGS. 28 and 30, in some embodiments, a waveguide 37 can be aligned to the energy conversion device 33 for ensuring the light energy arriving at the energy conversion device 33 is uniform. A laser source assembly 36 can be used to provide sufficient light energy to the energy conversion device 33. The laser source assembly 36 is connected to the waveguide 37. Preferably, the laser source assembly 36 includes a fiber link 362 and a laser 364. The fiber link 362 is connected to the waveguide 37. The laser 364 is coupled to the fiber link 362. Thus the laser light W can arrive at the energy conversion device 33 through the fiber link 362 and the waveguide 37. In some embodiments, the waveguide 37 can be used to seal the energy conversion device 33.

Referring to FIGS. 28 and 29 again, the first fin F1 and the second fin F2 are originating from inside the energy conversion device 33 and are spaced from each other. In this embodiment, the first fin F1 and the second fin F2 are formed from different metal contacts 338 and are spaced with the first end contact 334 and the second end contact 336. In addition, the energy conversion device 33 has two end surfaces 33S, and the first fin F1 and the second fin F2 are respectively protruding from different end surfaces 33S.

In this embodiment, the first fin F1 and the second fin F2 can be regarded as common ground fins, and the first end contact 334 and the second end contact 336 can be regarded as anode. Therefore, the first end contact 334 and the first fin F1 can output a first voltage V1. The first end contact 334 and the second fin F2 can output a second voltage V2. Furthermore, the second end contact 336 and the first fin F1 can output a third voltage V3, and the second end contact 336 and the second fin F2 can output a fourth voltage V4. For a 10 mm×5 mm VMJ cell, the first voltage V1, the second voltage V2, third voltage V3 and the fourth voltage V4 can be 9.9 V, 6.6 V, 3.3 V, and 6.6 V, respectively. They are enough isolated voltages to meet the requirements of the gate driver 32.

For the power transistor module 30, the use of the energy conversion device 33 contributes a cost and weight reduction because it does not need magnetic cores.

The description is given here to enable those of ordinary skill in the art to practice the invention. Many configurations are possible using the instant teachings, and the configurations and arrangements given here are only illustrative.

Those with ordinary skill in the art will, based on these teachings, be able to modify the invention as shown.

The invention as disclosed using the above examples may be practiced using only some of the optional features mentioned above. Also, nothing as taught and claimed here shall preclude addition of other reflective structures or optical elements.

Obviously, many modifications and variations of the present invention are possible in light of the above teaching. It is therefore to be understood that, within the scope of the appended claims, the invention may be practiced otherwise than as specifically described or suggested here.

What is claimed is:

1. An energy conversion device in electrical communication with at least one fin for outputting multiple voltages, said at least one fin
[1] originating from inside said energy conversion device;
[2] formed from a metal contact disposed between energy conversion device components; and
[3] spaced with a first end contact and a second end contact.

2. The energy conversion device of claim 1, wherein said energy conversion device components are stacked such that all the energy conversion device components have their positive charged side facing the same direction, or stacked such that the energy conversion device components have their positive charged side reversed on the other side of the metal contact.

3. The energy conversion device of claim 1, wherein said energy conversion device components are reversed on the other side of the metal contact, wherein the number of junctions between end contacts and metal contacts, and between metal contacts, are the same.

4. The energy conversion device of claim 1, wherein said energy conversion device is in thermal communication with said at least one fin.

5. The energy conversion device of claim 1, wherein said at least one fin is a common ground fin, enabled by reversing of the energy conversion device components on the other side of the fin.

6. The energy conversion device of claim 5, wherein the first end contact and said common ground fin output a first voltage, and the second end contact and said common ground fin output a second voltage.

7. The energy conversion device of claim 6, wherein a distance is between the first end contact and said common ground fin, and the first voltage is directly proportional to the distance.

8. The energy conversion device of claim 6, wherein a distance is between the first end contact and said common ground fin, and the second voltage is inversely proportional to the distance.

9. The energy conversion device of claim 1, wherein said energy conversion device is in electrical communication with a first fin and a second fin.

10. The energy conversion device of claim 9, wherein the first end contact and the first fin output a first voltage, the second end contact and the second fin output a second voltage, and the first and second fins output a third voltage.

11. The energy conversion device of claim 10, wherein a distance is between the first end contact and the first fin, and the first voltage is directly proportional to the distance.

12. The energy conversion device of claim 10, wherein a distance is between the first end contact and the first fin, and the sum of the second and third voltages is inversely proportional to the distance.

13. The energy conversion device of claim 1, wherein said energy conversion device is a vertical multijunction (VMJ) cell, and said energy conversion device components are cell junctions of the vertical multijunction (VMJ) cell.

14. The energy conversion device of claim 1, wherein the metal contact is made of aluminum, kovar, copper, or any other electrically conducive metal.

15. The energy conversion device of claim 1, wherein said energy conversion device has an end surface, and said at least one fin is protruding from the end surface.

16. The energy conversion device of claim 1, wherein said energy conversion device has a top surface, and said at least one fin is protruding from the top surface.

17. The energy conversion device of claim 1, wherein said energy conversion device has a bottom surface, and said at least one fin is protruding from the bottom surface.

18. A power transistor module, comprising:
at least one transistor;
a gate driver configured to drive said at least one transistor; and
the energy conversion device according to claim 1 configured to supply isolated voltages to the gate driver.

19. The power transistor module of claim 18, wherein said at least one transistor is an insulated gate bipolar transistor (IGBT) or a metal-oxide-semiconductor field effect transistor (MOSFET).

20. The power transistor module of claim 18, further comprising a heat sink, wherein said at least one transistor and the energy conversion device are disposed on the heat sink.

21. The power transistor module of claim 20, further comprising a thermal interface material disposed between the energy conversion device and the heat sink.

22. The power transistor module of claim 18, further comprising a waveguide aligned to the energy conversion device.

23. The power transistor module of claim 22, further comprising a laser source assembly connected to the waveguide.

24. The power transistor module of claim 23, wherein the laser source assembly includes a fiber link and a laser, the fiber link is connected to the waveguide, and the laser is coupled to the fiber link.

25. An energy conversion device, comprising:
a vertical multijunction (VMJ) cell comprising two end contacts and a plurality of cell junctions disposed between the two end contacts; and
a plurality of lead wires respectively bonded to the end contacts.

26. The energy conversion device of claim 25, wherein the VMJ cell comprises at least one metal contact disposed between the cell junctions.

27. The energy conversion device of claim 26, wherein one of the lead wires is bonded to the metal contact.

28. The energy conversion device of claim 25, further comprising a submount, wherein the submount has a plurality of electrically conductive pads, and the lead wires are respectively connected to the electrically conductive pads.

29. The energy conversion device of claim 25, wherein the VMJ cell has a top surface, and the lead wires are bonded on the top surface.
